(19) United States
(12) Patent Application Publication
(10) Pub. No.: US 2013/0292164 A1
(43) Pub. Date: Nov. 7, 2013

(54) RIGID-FLEXIBLE PRINTED CIRCUIT BOARD AND METHOD FOR MANUFACTURING THE SAME

(71) Applicant: SAMSUNG ELECTRO-MECHANICS CO., LTD., Suwon (KR)

(72) Inventors: Jung Yong Park, Suwon (KR); Myeong Hui Jung, Suwon (KR); Jae Woo Joung, Suwon (KR); Dae Hyung You, Suwon (KR)

(73) Assignee: SAMSUNG ELECTRO-MECHANICS CO., LTD., Suwon (KR)

(21) Appl. No.: 13/870,850

(22) Filed: Apr. 25, 2013

(30) Foreign Application Priority Data
May 7, 2012 (KR) 10-2012-0048139

(51) Int. Cl. H05K 3/10; H05K 1/18

(52) U.S. Cl. CPC H05K 3/10; H05K 1/181
USPC 174/260; 29/846

(57) ABSTRACT

Disclosed herein is a rigid-flexible substrate including: a rigid area including a circuit layer; a flexible area formed at one end of the rigid area; and a raw material formed over the flexible area and having indentation formed on a surface thereof.

### CROSS REFERENCE TO RELATED APPLICATION

This application claims the benefit of Korean Patent Application No. 10-2012-0048139, filed on May 7, 2012, entitled “Rigid-Flexible Printed Circuit Board And Method For Manufacturing Thereof” which is hereby incorporated by reference in its entirety into this application.

### BACKGROUND OF THE INVENTION

1. Technical Field

The present invention relates to a rigid-flexible printed circuit board and a method for manufacturing the same.

2. Description of the Related Art

With the recent development of IT industries, contents such as multimedia, and the like, are increased and with the development of network communication technology, a demand for a high-density, high-integration printed circuit board technology for ultra-high speed communication has increased. In addition, as a demand for slimness and lightness of mobile devices is increased, a demand for a technology for implementing miniaturization, lightness, thinness, multi-function, and various designs of the printed circuit board has increased.

As described above, as a design of high-density electronic devices is diversified, applications of a rigid-flexible printed circuit board have been increased.

The rigid-flexible printed circuit board uses both of a multi-layer printed circuit board technology and a flexible technology. That is, the rigid-flexible printed circuit board includes a flexible area in which circuit patterns are formed on a flexible film having flexibility and a rigid area in which physical hardness is increased by multi-layering insulating layers on a flexible film. (U.S. Pat. No. 5,362,534).

The rigid-flexible printed circuit board can be wired in a three-dimensional structure and easily assemble and therefore, can be applied to notebooks, digital cameras, mobile communication terminals, and the like.

### SUMMARY OF THE INVENTION

The present invention has been made in an effort to provide a rigid-flexible substrate and a method for manufacturing the same capable of improving adhesion of raw materials.

According to a preferred embodiment of the present invention, there is provided a rigid-flexible substrate, including: a rigid area including a circuit layer; a flexible area formed at one end of the rigid area; and a raw material formed over the flexible area and having indentation formed on a surface thereof.

The raw material may be an electronic element.

The raw material may be an electro magnetic interference (EMI) device.

According to a preferred embodiment of the present invention, there is provided a method for manufacturing a rigid-flexible substrate, including: providing a base substrate including a rigid area including a circuit layer and a flexible area; forming a raw material in the flexible area; forming a first subsidiary material over the rigid area and the flexible area; forming a first jig on the first subsidiary material; providing heat to the base substrate on which the raw material, the first subsidiary material, and the first jig are formed; and removing the first subsidiary material and the first jig.

In the forming of the raw material, the raw material may be an electronic element.

In the forming of the raw material, the raw material may be an electro magnetic interference (EMI) element.

In the forming of the first subsidiary material, the subsidiary material may be formed of a thermoplastic material.

In the forming of the first subsidiary material, the subsidiary material may be formed of poly vinyl chloride (PVC).

In the forming of the first jig, the first jig may include a first body that is extendedly formed longitudinally and a first protrusion that is formed beneath a portion of the first body and is protruded from the first body.

In the forming of the first jig, the first protrusion may be disposed over an area in which the raw material is disposed.

The method may further include: after the forming of the first subsidiary material, forming a second subsidiary material under the rigid area and the flexible area.

In the forming of the second subsidiary material, the second subsidiary material may be formed of a thermoplastic material.

In the forming of the second subsidiary material, the second subsidiary material may be formed of poly vinyl chloride (PVC).

The method may further include: after the forming of the second subsidiary material, forming a second jig beneath the second subsidiary material.

In the forming of the second jig, the second jig may include a second body that is extendedly formed longitudinally and a second protrusion that is formed beneath a portion of the second body and is protruded from the second body.

In the forming of the second jig, the second protrusion may be disposed under an area in which the raw material is disposed.

### BRIEF DESCRIPTION OF THE DRAWINGS

The above and other objects, features and advantages of the present invention will be more clearly understood from the following detailed description taken in conjunction with the accompanying drawings, in which:

FIGS. 1 to 6 are diagrams showing a method for manufacturing a rigid-flexible substrate according to a preferred embodiment of the present invention;

FIGS. 7 to 12 are diagrams showing the method for manufacturing a rigid-flexible substrate according to the preferred embodiment of the present invention;

FIG. 13 is a diagram showing a rigid-flexible substrate when jigs are not used according to the embodiment of the present invention; and

FIG. 14 is a diagram showing a rigid-flexible substrate when jigs are used according to the embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

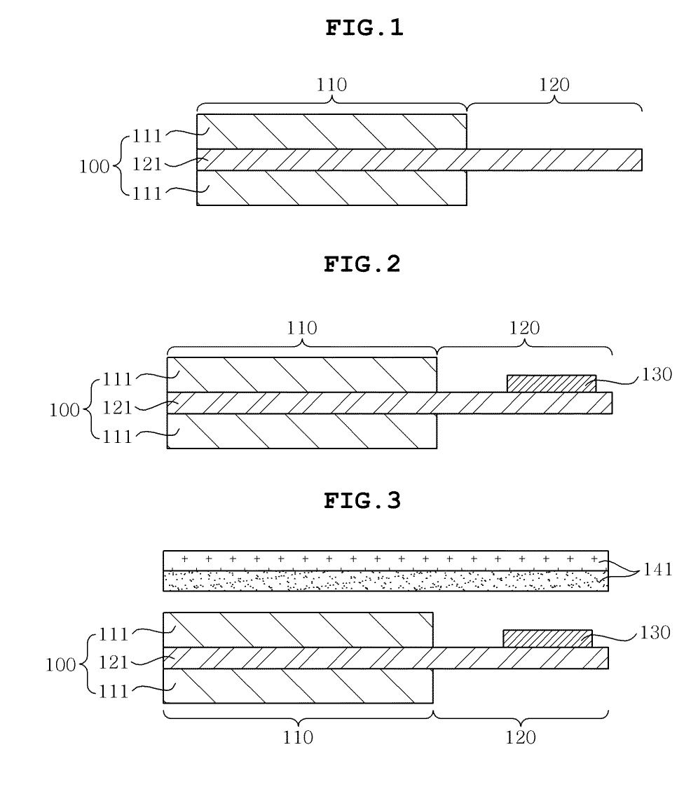

FIGS. 1 to 6 are diagrams showing a method for manufacturing a rigid-flexible substrate according to a preferred embodiment of the present invention.

Referring to FIG. 1, a rigid area 110 including a circuit layer (not shown) and a base substrate 100 including a flexible area 120 may be provided.

The flexible area 120 may be formed as a flexible substrate 121 on which the circuit layer (not shown) is formed.

The flexible substrate 121 may be formed of an insulating material. In addition, the flexible substrate 121 may have excellent flexibility. The flexible substrate 121 may be formed of polyimide. However, the material of the flexible substrate 121 is not limited to polyimide. That is, as the material of the flexible substrate 121 any insulating material having property including flexibility can be used. The flexible substrate 121 may include a circuit layer (not shown).

The rigid area 110 may be formed as a rigid substrate 111 on which the circuit layer (not shown) is formed. In addition, the rigid area 110 may include the flexible substrate 121. The rigid area 110 may include the flexible substrate 121, insulating layers (not shown) on top and bottom of the flexible substrate 121, and the circuit layer (not shown) including circuit patterns, vias, and the like. In this case, the rigid area 110 may be formed to have a thickness thicker than that of the flexible area 120.

Referring to FIG. 2, a raw material 130 may be formed in the flexible area 120. The raw material 130 may be disposed on the top of the flexible substrate 121 of the flexible area 120. The bottom of the raw material 130 contacting the flexible substrate 121 may be previously formed with an adhesive material. The raw material 130 may be electronic elements. For example, the raw material 130 may be an electro magnetic interference (EMI) element for preventing a function from being degraded due to noises. The raw material 130 is not limited to the EMI element. That is, as the raw material 130, any material which can be bonded to the flexible substrate can be used.

Referring to FIG. 3, a first subsidiary material 141 may be formed over the rigid area 110 and the flexible area 120. The first subsidiary material 141 may extend from above the rigid area 110 to the top of the raw material 130 that is formed in the flexible area 120. In this case, the first subsidiary material 141 may be formed so as to be bonded to the top of the base substrate 100.

The first subsidiary material 141 may be formed of a thermoplastic material. For example, the first subsidiary material 141 may be formed of poly vinyl chloride (PVC). The first subsidiary material 141 may serve to transfer heat to the raw material 130. The first subsidiary material 141 is formed of a thermoplastic material and thus, the shape thereof may be changed in a high-temperature state.

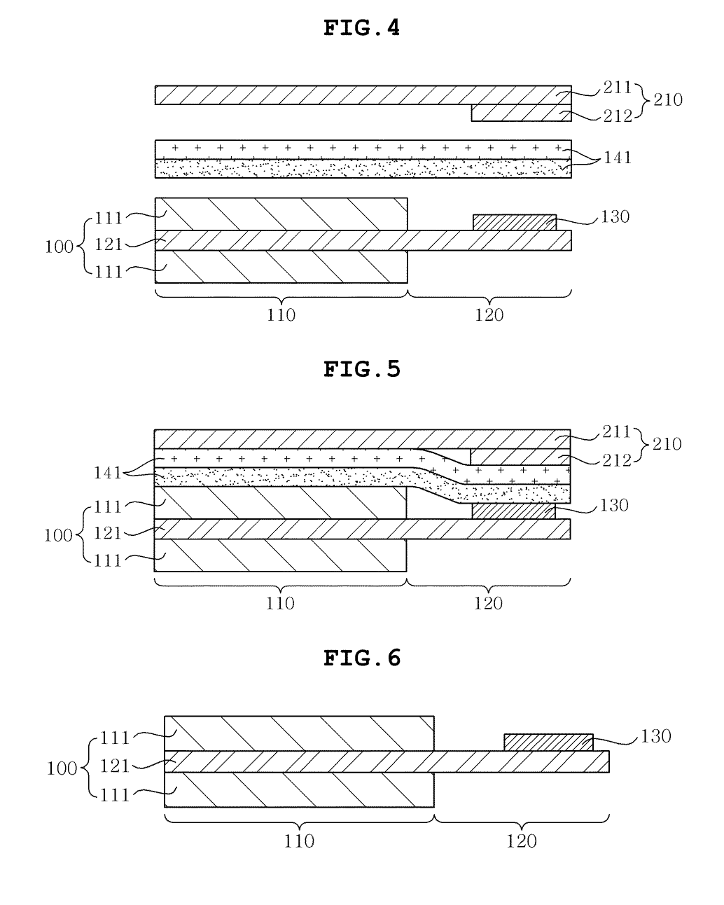

Referring to FIG. 4, a first jig 210 may be formed on the first subsidiary material 141.

The first jig 210 may be formed to include a first body 211 and a first protrusion 212.

The first body 211 may be extendedly formed longitudinally. A length of the first body 211 may be formed enough to partially cover at least the rigid area 110 and the flexible area 120. For example, the first body 211 may be formed to cover a portion or all of the rigid area 110. Further, the first body 211 may be formed to cover a portion or all of the flexible area 120. In this case, when the first body 211 partially covers the flexible area 120, the first body 211 may be formed to have a length enough to cover an area in which the raw material 130 is formed.

The first protrusion 212 may be formed beneath the first body 211. The first protrusion 212 may be protruded from the first body 211. In this case, the first protrusion 212 may be formed to have a thickness enough to contact a bottom surface of the first subsidiary material 141 to a top surface of the raw material 130.

When the first jig 210 is disposed on the first subsidiary material 141, the first protrusion 212 of the first jig 210 may be disposed on the raw material 130.

The first jig 210 may be formed of a copper clad laminate (CCL), an epoxy resin, and the like. For example, the first body 211 of the first jig 210 is formed of the CCL and the first protrusion 212 may be formed of the epoxy resin. However, the first jig 210 is not limited thereto and therefore, may be formed of a material having heat resistance but does not include flexibility.

Referring to FIG. 5, heat may be transferred to the base substrate 100.

Heat may transfer to the base substrate 100 on which the raw material 130, the first subsidiary material 141, and the first jig 210 are formed. As described above, as the base substrate 100 is in a high temperature state, the shape of the first subsidiary material 141 can be modified.

For example, when the rigid area 110 is formed to have a thickness thicker than that of the flexible area 120, there may be a difference in a height between the rigid area 110 and the flexible area 120. In this case, the first subsidiary material 141 formed over the rigid area 110 and the flexible area 120 may be bent in the high-temperature state due to the height difference therebetween. That is, the first subsidiary material 141 may extend downwardly from the flexible area 120. The first subsidiary material 141 may extend to the top surface of the raw material 130 of the flexible area 120. In this case, the first subsidiary material 141 may contact the top surface of the raw material 130.

In addition, the first subsidiary material 141 may be pressed by the first jig 210 formed thereon. That is, the first protrusion 212 of the first jig 210 may press the first subsidiary material 141 formed therebeneath. As such, as the first subsidiary material 141 is pressed by the first protrusion 212 of the first jig 210, a contact area between the first subsidiary material and the top surface of the raw material 130 may be increased.

As the contact area between the first subsidiary material 141 and the raw material 130 is increased by the high temperature and the pressure of the first jig 210, heat is sufficiently transferred to the raw material 130 through the first subsidiary material 141.

The raw material 130 may be supplied with sufficient heat through the first subsidiary material 141 to increase an adhesion of an adhesive material formed on the bottom surface of the raw material 130. The raw material 130 is supplied with sufficient heat to increase adhesion and may be reliably bonded to the flexible substrate 121.

Referring to FIG. 6, the first subsidiary material 141 and the first jig 210 may be removed.

After the raw material 130 is reliably bonded to the flexible substrate 121, the first subsidiary material 141 and the first jig 210 may be removed. The first subsidiary material 141 and the first jig 210 may be removed by being detached or stripped from the base substrate 100 and the raw material 130.

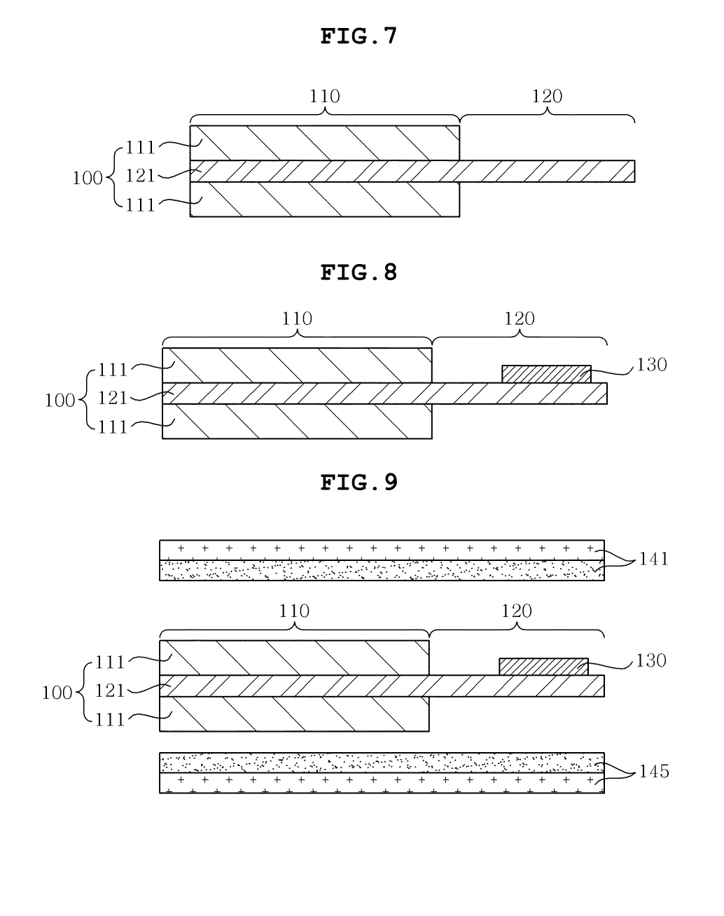

FIGS. 7 to 12 are diagrams showing the method for manufacturing a rigid-flexible substrate according to the preferred embodiment of the present invention.

Referring to FIG. 7, the rigid area 110 including the circuit layer (not shown) and the base substrate 100 including the flexible area 120 may be provided.

The flexible area 120 may be formed as the flexible substrate 121 on which the circuit layer (not shown) is formed.

The flexible substrate 121 may be formed of an insulating material. In addition, the flexible substrate 121 may have excellent flexibility. The flexible substrate 121 may be formed of polyimide. However, the material of the flexible substrate 121 is not limited to polyimide. That is, as the material of the flexible substrate 121 any insulating material having property including the flexibility can be used. The flexible substrate 121 may include the circuit layer (not shown). The flexible substrate 121 may include the circuit layer (not shown).

The rigid area 110 may be formed as the rigid substrate 111 on which the circuit layer (not shown) is formed. In addition, the rigid area 110 may include the flexible substrate 121. In this case, the flexible substrate 121 may include the circuit layer (not shown). The rigid area 110 may include the flexible substrate 121, the insulating layers (not shown) on the top and bottom of the flexible substrate 121, and the circuit layer (not shown) including circuit patterns, vias, and the like. In this case, the rigid area 110 may be formed to have a thickness thicker than that of the flexible area 120.

Referring to FIG. 8, the raw material 130 may be formed in the flexible area 120. The raw materials 130 may be disposed on the top of the flexible substrate 121 of the flexible area 120. The bottom of the raw material 130 contacting the flexible substrate 121 may be previously formed with an adhesive material. The raw material 130 may be electronic elements. For example, the raw material 130 may be the electro magnetic interference (EMI) element for preventing a function from being degraded due to noises. The raw material 130 is not limited to the EMI element. That is, as the raw material 130, any material which can be bonded to the flexible substrate can be used.

Referring to FIG. 9, the first subsidiary material 141 and the second subsidiary material 145 may be formed on the base substrate 100 on which the raw material 130 is formed. The first subsidiary material 141 may be formed over the rigid area 110 and the flexible area 120. The first subsidiary material 141 may extend from above the rigid area 110 to the top of the raw material 130 that is formed in the flexible area 120. The second subsidiary material 145 may be formed under the rigid area 110 and the flexible area 120. The second subsidiary material 145 may extend from under the rigid area 110 to the bottom of the raw material 130 that is formed in the flexible area 120. The first subsidiary material 141 and the second subsidiary material 145 may be formed so as to be bonded to the top and bottom of the base substrate 100.

The first subsidiary material 141 and the second subsidiary material 145 may be made of a thermoplastic material. For example, the first subsidiary material 141 and the second subsidiary material 145 may be made of poly vinyl chloride (PVC). The first subsidiary material 141 and the second subsidiary material 145 may serve to transfer heat to the raw material 130. The first subsidiary material 141 and the second subsidiary material 145 is made of a thermoplastic material and thus, the shape thereof may be changed in a high-temperature state.

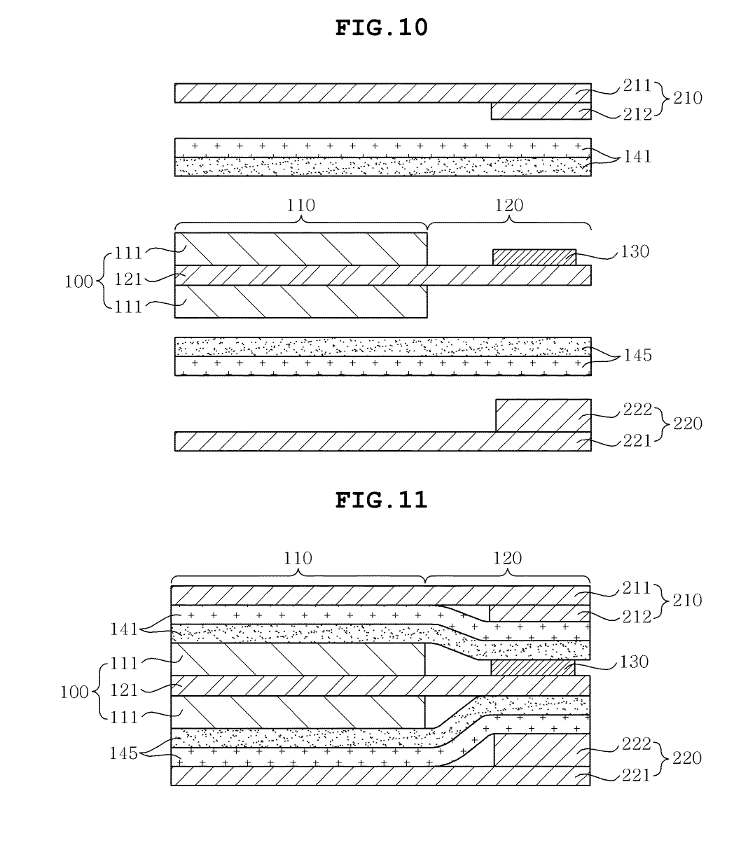

Referring to FIG. 10, the first jig 210 may be formed on the first subsidiary material 141. In addition, a second jig 220 may be formed beneath the second subsidiary material 145.

The first jig 210 may be formed to include a first body 211 and a first protrusion 212.

The first body 211 may be extendedly formed longitudinally. The length of the first body 211 may be formed enough to partially cover at least the rigid area 110 and the flexible area 120. In this case, when the first body 211 partially covers the flexible area 120, the first body 211 may be formed to have a length enough to cover an area in which the raw material 130 is formed.

The first protrusion 212 may be formed under the first body 211. The first protrusion 212 may be protruded from the first body 211. In this case, the first protrusion 212 may be formed to have a thickness enough to contact a bottom surface of the first subsidiary material 141 to a top surface of the raw material 130.

The second jig 220 may be formed to include a second body 221 and a second protrusion 222.

The second body 221 may be extendedly formed longitudinally. The length of the second body 221 may be formed enough to partially cover the rigid area 110 and the flexible area 120 at least. In this case, when the second body 221 partially covers the flexible area 120, the second body 221 may be formed to have a length enough to cover an area in which the raw material 130 is formed.

The second protrusion 222 may be formed on the second body 221. The second protrusion 222 may be protruded from the second body 221. In this case, the second protrusion 222 may be formed to have a thickness enough to contact a top surface of the second subsidiary material 145 to a bottom surface of the flexible substrate 121.

When the first jig 210 is disposed on the first subsidiary material 141, the first protrusion 212 of the first jig 210 may be disposed on the raw material 130. In addition, when the second jig 220 is disposed beneath the first subsidiary material 145, the second protrusion 222 of the second jig 220 may be disposed under the raw material 130. In this case, the first protrusion 212 of the first jig 210 and the second protrusion 222 of the second jig 220 may be disposed to face each other.

The first jig 210 and the second jig 220 may be formed of a copper clad laminate (CCL), an epoxy resin, and the like. For example, the first body 211 of the first jig 210 is formed of the CCL and the first protrusion 212 may be formed of the epoxy resin. However, the first jig 210 is not limited thereto and therefore, may be formed of a material having heat resistance but does not include flexibility. The second jig 220 may be formed of the same material as the first jig 210.

Referring to FIG. 11, heat may be transferred to the base substrate 100.

Heat may transfer to the base substrate 100 on which the raw material 130, the first subsidiary material 141, the second subsidiary material 145, the first jig 210, and the second jig 220 are formed. As described above, as the base substrate 100 is in a high temperature state, the shape of the first subsidiary material 141 and the second subsidiary material 145 can be modified.

For example, when the rigid area 110 is formed to have a thickness thicker than that of the flexible area 120, there may be a difference in a height between the rigid area 110 and the flexible area 120. In this case, the first subsidiary material 141 and the second subsidiary material 145 formed over and under the rigid area 110 and the flexible area 120 may be bent in the high-temperature state due to the height difference therebetween.

The first subsidiary 141 may extend to the top surface of the raw material 130 of the flexible area 120. In this case, the first subsidiary material 141 may contact the top surface of the raw material 130.

The second subsidiary material 145 may extend to the flexible substrate 121 of the flexible area 120. In this case, the second subsidiary material 145 may contact the bottom surface of the flexible substrate 121.

In addition, the first subsidiary material 141 may be pressed by the first jig 210 formed thereon. That is, the first protrusion 212 of the first jig 210 may press the first subsidiary material 141 formed therebeneath. As such, as the first subsidiary material 141 is pressed by the first protrusion 212 of the first jig 210, a contact area between the first subsidiary material 141 and the top surface of the raw material 130 may be increased.

The second subsidiary material 145 may be pressed by the second jig 220 formed therebeneath. That is, the second protrusion 222 of the second jig 220 may press the second subsidiary material 145 formed thereon. As such, as the second subsidiary material 145 is pressed by the second protrusion 222 of the second jig 220, a contact area between the second subsidiary material 145 and the bottom surface of the flexible substrate 121 on which the raw material 130 is formed may be increased.

As the contact area between the first subsidiary material 141 and the raw material 130 is increased by the high temperature and the pressure of the first jig 210 and the second jig 220, heat is sufficiently transferred to the raw material 130 through the first subsidiary material 141.

The raw material 130 may be supplied with sufficient heat through the first subsidiary material 141 to increase an adhesion of an adhesive material formed on the bottom surface of the raw material 130. The raw material 130 is supplied with sufficient heat to increase adhesion and may be reliably bonded to the flexible substrate 121.

According to the preferred embodiment of present invention, the first subsidiary material 141 and the second subsidiary material 145 simultaneously may press the top and bottom of the raw material 130 by the first jig 210 and the second jig 220. That is, the raw material 130 and the flexible substrate 121 may be more firmly bonded to each other. Therefore, the flexible substrate 121 may be improved, in the case in which two subsidiary materials and jigs are used, the adhesion between the raw material 130 and the flexible substrate 121 and than in the case in which one subsidiary material and a jig are used.

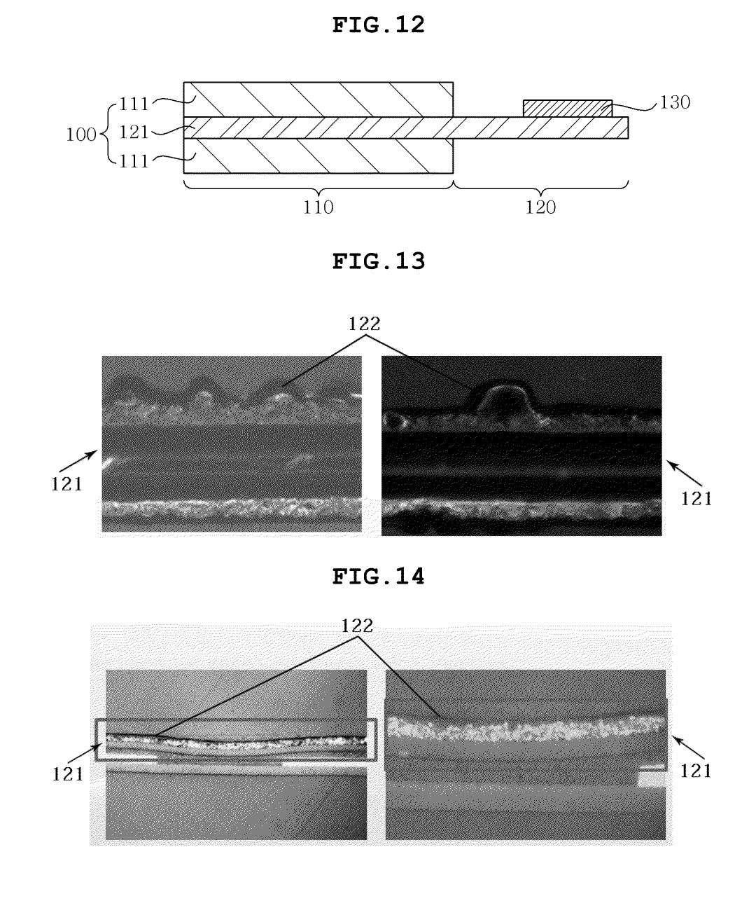

Referring to FIG. 12, the first subsidiary material 141, the second subsidiary material 145, the first jig 210, and the second jig 220 may be removed.

After the raw material 130 is reliably bonded to the flexible substrate 121, the first subsidiary material 141, the second subsidiary material 145, the first jig 210, and the second jig 220 may be removed. The first subsidiary material 141, the second subsidiary material 145, the first jig 210, and the second jig 220 may be removed by being detached or stripped from the base substrate 100 and the raw material 130.

FIG. 13 is a diagram showing the surface of the rigid-flexible substrate when the jigs are not used according to the embodiment of the present invention.

Referring to FIG. 13, it can confirm the surface 122 of the flexible substrate 121 when the jigs are not used. The flexible substrate 121 may be formed with wrinkles since the surface 122 thereof is melted during a high-temperature high-pressure process. Referring to FIG. 13, it can be confirmed that the surface 122 of the flexible substrate 121 may be formed with wrinkles. When the raw material 130 of FIG. 3 is bonded to the surface of the flexible substrate 121 formed with wrinkles, a gap may occur between the surface 122 of the flexible substrate 121 and the bottom surface of the raw material 130 of FIG. 3. In this case, when the raw material 130 of FIG. 3 is not sufficiently supplied with heat and pressure from the first subsidiary material 141 of FIG. 3, it is difficult to reliably bond between the flexible substrate 121 the raw material 130 of FIG. 3.

FIG. 14 is a diagram showing the surface of the rigid-flexible substrate when the jigs are used according to the embodiment of the present invention.

Referring to FIG. 14, it can confirm the surface 122 of the flexible substrate 12 when the jigs are not used. The flexible substrate 121 may be formed with wrinkles since the surface 122 thereof is melted during a high-temperature high-pressure process as shown in FIG. 13. When the raw material 130 of FIG. 5 is bonded to the surface 122 of the flexible substrate 121 formed with wrinkles, pressure may be applied to the first subsidiary material 141 of FIG. 4 that is formed on the raw material 130 of FIG. 5, by using the first jig 210 of FIG. 5. The first subsidiary material 141 of FIG. 4 may apply pressure to the flexible substrate 121 and the raw material 130 of FIG. 5, by the pressure of the first jig 210 of FIG. 5. In this case, the flexible substrate 121 and the raw material 130 of FIG. 5 may be applied with pressure from the first subsidiary material 141 of FIG. 5 and the first jig 210 of FIG. 5 to be bonded to each other. As described above, the surface 122 of the flexible substrate 121 is bonded to the bottom of the raw material 130 of FIG. 5 by pressure and thus, the surface 122 of the flexible substrate 121 may be flat as shown in FIG. 14. As the surface 122 of the flexible substrate 121 is flat, the contact area between the surface 122 of the flexible substrate 121 and the raw material 130 of FIG. 5 may be increased. As described above, when sufficient heat for bonding is supplied from the first subsidiary material 141 of FIG. 5 in the state in which the contact area between the surface 122 of the flexible substrate 121 and the raw material 130 of FIG. 5 is increased, the flexible substrate 121 and the raw material 130 of FIG. 5 can be reliably bonded to each other.

In the preferred embodiments of FIGS. 13 and 14, the first jig 210 and the first subsidiary material 141 are described by way of example, but are not limited thereto. That is, when the first jig 210 and the first subsidiary material 141 are used, the second jig 220 and the second subsidiary material 142 may be simultaneously used.

According to the preferred embodiment of the present invention, when the raw material is bonded to the flexible area of the base substrate, the jigs formed with the protrusions are used and thus, the sufficient heat may be transferred to the raw material through the subsidiary materials. Therefore, it is prevent the raw material from being lifted due to the increase in the adhesion of the raw material and the raw material from separating from each other due to pores formed between the raw material and the base substrate, and the like.

According to the rigid-flexible substrate and the method for manufacturing the same, it is possible to improve the adhesion of the raw material bonded to the flexible area.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A rigid-flexible substrate, comprising:
a rigid area including a circuit layer;
a flexible area formed at one end of the rigid area; and
a raw material formed over the flexible area and having indentation formed on a surface Thereof.

2. The rigid-flexible substrate as set forth in claim 1, wherein the raw material is an to electronic element.

3. The rigid-flexible substrate as set forth in claim 1, wherein the raw material is an electro magnetic interference (EMI) device.

4. A method for manufacturing a rigid-flexible substrate, the method comprising:
providing a base substrate including a rigid area including a circuit layer and a flexible area;
forming a raw material in the flexible area;
forming a first subsidiary material over the rigid area and the flexible area;
forming a first jig on the first subsidiary material;
providing heat to the base substrate on which the raw material, the first subsidiary material, and the first jig are formed; and
removing the first subsidiary material and the first jig.

5. The method as set forth in claim 4, wherein in the forming of the raw material, the raw material is an electronic element.

6. The method as set forth in claim 4, wherein in the forming of the raw material, the raw material is an electro magnetic interference (EMI) element.

7. The method as set forth in claim 4, wherein in the forming of the first subsidiary material, the subsidiary material is formed of a thermoplastic material.

8. The method as set forth in claim 4, wherein in the forming of the first subsidiary material, the subsidiary material is formed of poly vinyl chloride (PVC).

9. The method as set forth in claim 4, wherein in the forming of the first jig, the first jig includes a first body that is extendedly formed longitudinally and a first protrusion that is formed beneath a portion of the first body and is protruded from the first body.

10. The method as set forth in claim 9, wherein in the forming of the first jig, the first protrusion is disposed over an area in which the raw material is disposed.

11. The method as set forth in claim 4, further comprising: after the forming of the first subsidiary material, forming a second subsidiary material under the rigid area and the flexible area.

12. The method as set forth in claim 11, wherein in the forming of the second subsidiary material, the second subsidiary material is formed of a thermoplastic material.

13. The method as set forth in claim 11, wherein in the forming of the second subsidiary material, the second subsidiary material is formed of poly vinyl chloride (PVC).

14. The method as set forth in claim 11, further comprising: after the forming of the second subsidiary material, forming a second jig beneath the second subsidiary material.

15. The method as set forth in claim 14, wherein in the forming of the second jig, the second jig includes a second body that is extendedly formed longitudinally and a second protrusion that is formed beneath a portion of the second body and is protruded from the second body.

16. The method as set forth in claim 15, wherein in the forming of the second jig, the second protrusion is disposed under an area in which the raw material is disposed.
